(19) United States
(12) Patent Application Publication
(10) Pub. No.: US 2026/0201537 A1
(43) Pub. Date: Jul. 16, 2026

(54) DEPOSITION MASK, METHOD OF MANUFACTURING DISPLAY DEVICE, AND ELECTRONIC DEVICE

(71) Applicant: Samsung Display Co., LTD., Yongin-si (KR)

(72) Inventors: Jung Sun PARK, Yongin-si (KR); A Reum LEE, Yongin-si (KR); Joon Gu LEE, Yongin-si (KR)

(21) Appl. No.: 19/355,679

(22) Filed: Oct. 10, 2025

(30) Foreign Application Priority Data
Jan. 13, 2025 (KR) 10-2025-0004735

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes: a frame in which an opening through which a deposition material passes is defined; and a mask sheet arranged on the frame, including at least one pattern region overlapping the opening in a direction through which the deposition material passes is formed. The frame includes a groove extending in a first direction, a first channel extending in a second direction intersecting the first direction and communicating with the groove, and a second channel extending in a third direction intersecting the first and second directions and communicating with the first channel. The first channel communicates the groove and the second channel with each other. The second channel includes an injection hole into which an external fluid is injected.

This application claims priority to Korean Patent Application No. 10-2025-0004735, filed on January 13, 2025, and all the benefits accruing therefrom under 35 U.S.C. §119, the content of which in its entirety is herein incorporated by reference.

### BACKGROUND

### 1. Technical Field

Embodiments of the present disclosure generally relate to a deposition mask, a method of manufacturing a display device, and an electronic device.

### 2. Description of the Related Art

With the development of information technology, the importance of a display device, which is a connection medium between a user and information, is being highlighted. In response to this, the use of display devices such as liquid crystal display devices and organic light emitting display devices is increasing.

For example, an organic light emitting display device may be used in a mobile device such as a smartphone, a computer, a tablet personal computer, or an electronic device such as a television, an outdoor billboard, or an exhibition display.

In the case of an organic light emitting display device, an anode electrode arranged on a substrate, a cathode electrode, and an organic light emitting layer interposed between the anode electrode and the cathode electrode may be included. The organic light emitting layer may be formed using a deposition mask.

The above description is only for the purpose of facilitating an understanding of the background art of the technical ideas of the present disclosure, and thus it cannot be understood as content corresponding to the prior art known to those skilled in the art of the present disclosure.

### SUMMARY

Aspects of some embodiments of the present disclosure provide a deposition mask capable of effectively removing a cleaning solution remained between a frame and a mask sheet, a method for manufacturing a display device, and an electronic device.

According to some embodiments of the present disclosure, a deposition mask includes: a frame in which an opening through which a deposition material passes is defined; and a mask sheet arranged on the frame, including at least one pattern region overlapping the opening in a direction through which the deposition material passes is formed. The frame includes a groove extending in a first direction, a first channel extending in a second direction intersecting the first direction and communicating with the groove, and a second channel extending in a third direction intersecting the first and second directions and communicating with the first channel. The first channel communicates the groove and the second channel with each other. The second channel includes an injection hole into which an external fluid is injected.

According to some embodiments, the first direction may be a longitudinal direction of the mask sheet. The second direction may be a thickness direction of the mask sheet. The third direction may be a latitudinal direction of the mask sheet.

According to some embodiments, a portion of the groove may be covered by one end of the mask sheet. Another portion of the groove may be exposed to the outside.

According to some embodiments, the frame may include a pair of long side rods having a first length, a pair of short side rods having a second length shorter than the first length. The groove, the first channel, and the second channel may be formed in the pair of long side rods.

According to some embodiments, the frame may further include a third channel extending in the first direction in at least one of the pair of short side rods and in communication with the second channel.

According to some embodiments, the second channel may include a (2_1)-th channel formed in any one of the pair of long side rods, and a (2_2)-th channel formed in another one of the pair of long side rods. The third channel may communicate the (2_1)-th channel and the (2_2)-th channel with each other.

According to some embodiments, the third channel may include a sub-injection hole into which an external fluid is injectable.

According to some embodiments, one side of the mask sheet and the other side of the mask sheet opposite to the one side in the third direction may overlap the frame in the second direction. The frame may further include a sub-groove extending in the third direction.

According to some embodiments, a portion of the sub-groove may be covered by the one side or the other side of the mask sheet. Another portion of the sub-groove may be exposed to the outside.

According to some embodiments, the frame may further include a sub-first channel communicating with the sub-groove and extending in the second direction, and a third channel communicating with the sub-first channel and extending in the first direction. The sub-first channel may communicate the sub-groove and the third channel with each other.

According to some embodiments, the third channel may include a sub-injection hole into which an external fluid is injectable.

According to some embodiments, the second channel and the third channel may be in communication with each other.

According to some embodiments, the groove may include first to n-th grooves (n is an integer of 1 or more) spaced apart from each other along the third direction. At least one of the first to n-th grooves may be covered by one end of the mask sheet. The remaining grooves of the first to n-th grooves other than the at least one of the first to n-th grooves may be exposed to the outside.

According to some embodiments of the present disclosure, a method of manufacturing a display device, includes: forming a patterned light emitting layer on a substrate using a deposition mask; immersing the deposition mask into a cleaning solution; removing the deposition mask from the cleaning solution and eliminating residual cleaning solution from the deposition mask; and repeating forming the patterned light emitting layer using the cleaned deposition mask. The deposition mask includes: a frame in which an opening through which a deposition material passes is defined; and a mask sheet arranged on the frame, including a plurality of pattern regions overlapping the opening in a direction through which the deposition material passes are formed. The frame includes a groove extending in a first direction, a first channel extending in a second direction intersecting the first direction and communicating with the groove, and a second channel extending in a third direction intersecting the first and second directions and communicating with the first channel. The groove and the second channel communicate with each other through the first channel. Eliminating the residual cleaning solution from the deposition mask includes injecting fluid into the second channel.

According to some embodiments, the fluid may sequentially flow through the second channel, the first channel, and the groove to dry the deposition mask.

According to some embodiments, the frame may include a pair of long side rods having a first length; and a pair of short side rods having a second length shorter than the first length. The groove, the first channel, and the second channel may be formed in the pair of long side rods. The deposition mask may further include a third channel extending in the first direction in at least one of the pair of short side rods and in communication with the second channel. Eliminating the residual cleaning solution from the deposition mask may further include injecting fluid into the third channel.

According to some embodiments, the second channel may include a (2_1)-th channel formed in any one of the pair of long side rods; and a (2_2)-th channel formed in another one of the pair of long side rods. The (2_1)-th channel and the (2_2)-th channel may communicate with each other through the third channel. The fluid injected into the third channel may flow into the (2_1)-th channel and the (2_2)-th channel.

According to some embodiments, the fluid may sequentially flow through the third channel, the second channel, the first channel, and the groove to dry the deposition mask.

According to some embodiments, one side of the mask sheet and the other side of the mask opposite to the one side in the third direction may overlap the frame in the second direction. The frame may further include a sub-groove extending in the third direction. The deposition mask may further include a sub first channel communicating with the sub-groove and extending in the second direction; and a third channel communicating with the sub-first channel and extending in the first direction. The sub-groove and the third channel may communicate with each other through the sub-first channel. The second channel and the third channel may be in communication with each other. The fluid may sequentially flow in the second channel, the third channel, the sub-first channel, and the sub-groove to dry the deposition mask.

According to some embodiments of the present disclosure, an electronic device includes: a processor; a plurality of pixels; and a display device configured to display an image on the plurality of pixels under control of the processor. The display device is manufactured by the method of manufacturing the display device above.

### BRIEF BESCRIOTION OF THE DRAWINGS

The above and other features of embodiments of the present disclosure will become more apparent by describing in further detail embodiments thereof with reference to the accompanying drawings; however, the subject matter of the present disclosure may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that if (e.g., when) an element is referred to as being "between" two elements, it can be the only element between the two elements, or one or more intervening elements may also be present. Like reference numerals refer to like elements throughout.

FIG. 1 is a perspective view illustrating an embodiment of a deposition mask.

FIG. 2 is a plan view illustrating the deposition mask shown in FIG. 1 as viewed from above.

FIG. 3 is a plan perspective view illustrating a frame of the deposition mask shown in FIG. 2 as viewed transparently.

FIG. 4 is a cross-sectional view illustrating a section taken along line A-A' of FIG. 3.

FIG. 5 is a cross-sectional view illustrating another embodiment of the first channel shown in FIG. 4.

FIG. 6 is a plan perspective view illustrating another embodiment of the frame shown in FIG. 3.

FIG. 7 is a cross-sectional view illustrating a section taken along line B-B' of FIG. 6.

FIG. 8 is a plan view illustrating another embodiment of the deposition mask shown in FIG. 2.

FIG. 9 is a plan perspective view illustrating the frame of the deposition mask shown in FIG. 8 as viewed transparently.

FIG. 10 is a cross-sectional view illustrating a section taken along line C-C' of FIG. 9.

FIG. 11 is a plan view illustrating an embodiment of a display device.

FIG. 12 is a plan view illustrating an embodiment of a sub-pixel shown in FIG. 11.

FIG. 13 is a cross-sectional view illustrating a section taken along line D-D' of FIG. 12.

FIG. 14 is a flowchart illustrating an embodiment of a method for manufacturing a display device.

FIG. 15 is a block diagram illustrating an embodiment of an electronic device including the display device shown in FIG. 11.

FIG. 16 is a perspective view illustrating an example of a smartphone implemented using the electronic device shown in FIG. 15.

FIG. 17 is a perspective view illustrating an example of a tablet computer implemented using the electronic device shown in FIG. 15.

### DETAILED DESCRIPTION

Hereinafter, aspects of some embodiments according to the present disclosure will be described in detail with reference to the accompanying drawings. In the description below, only the parts necessary to understand the operation according to the present disclosure are described, and descriptions of other parts will be omitted so as not to obscure the gist of the present disclosure. The present disclosure is not necessarily limited to the embodiments described herein, and may be embodied in other forms. However, the embodiments described herein are provided to explain in detail to a person skilled in the art that the technical idea of the present disclosure can be easily implemented.

In the entire specification, if (e.g., when) an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating an example embodiment and not intended to limit the embodiment. It will be understood that if (e.g., when) a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” “(2_1)-th”, “(2_2)-th”, etc. may be used herein to describe various elements, these elements should not be necessarily limited by these terms. These terms are only used to distinguish one element from another element. Thus, a “first” element discussed below could also be termed a “second” element without departing from the spirit and scope of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the example term, “above,” may encompass both an orientation of above and below. The apparatus may be otherwise oriented (e.g., rotated 90 degrees or at other orientations) and the spatially relative descriptors used herein interpreted accordingly.

Embodiments of the disclosure are described here with reference to schematic diagrams of idealized embodiments (and an intermediate structure) of the present disclosure, so that changes in a shape as shown due to, for example, manufacturing technology and/or a tolerance may be expected. Therefore, embodiments of the present disclosure shall not be necessarily limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

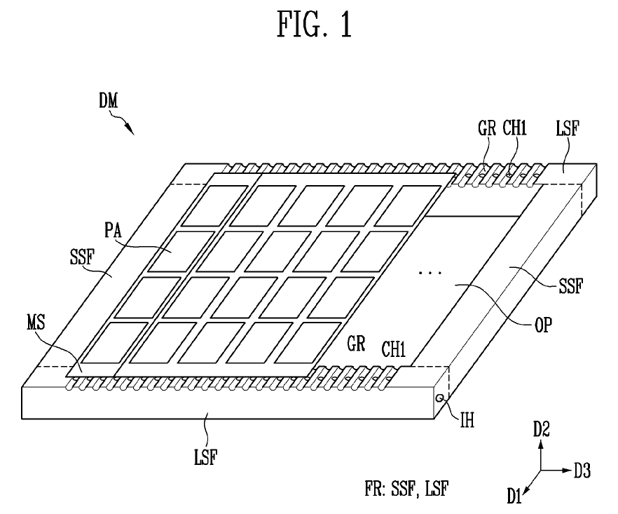

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. Hereinafter, a deposition mask DM will be described with reference to FIGS. 1 to 10.

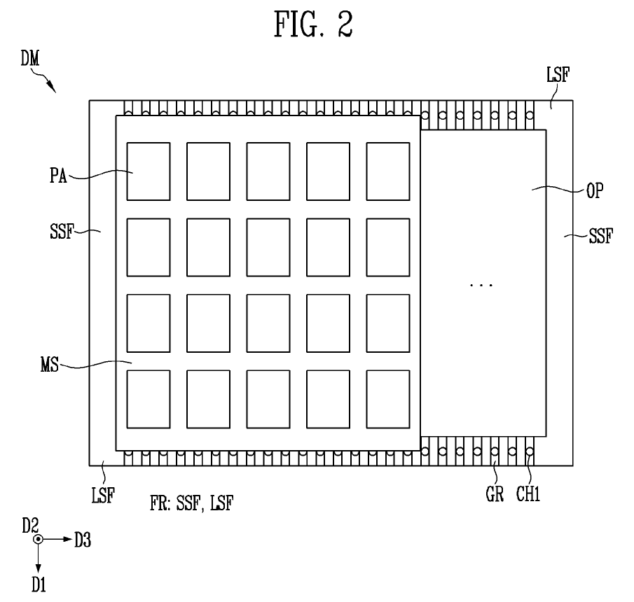

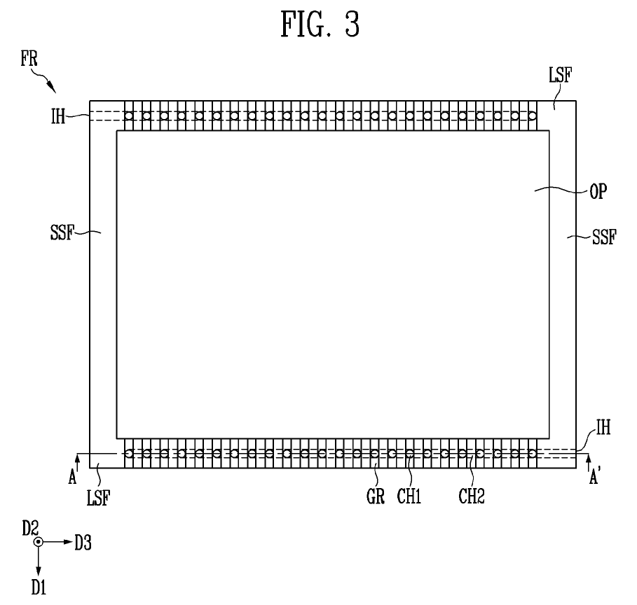

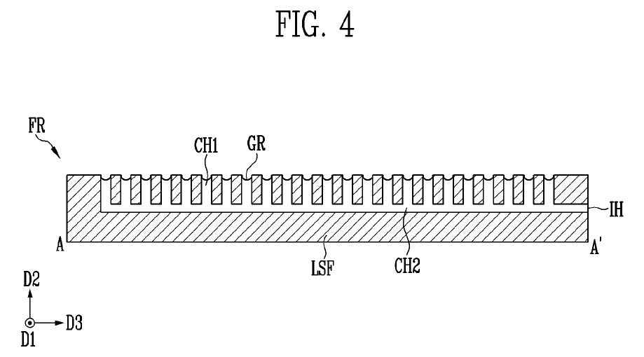

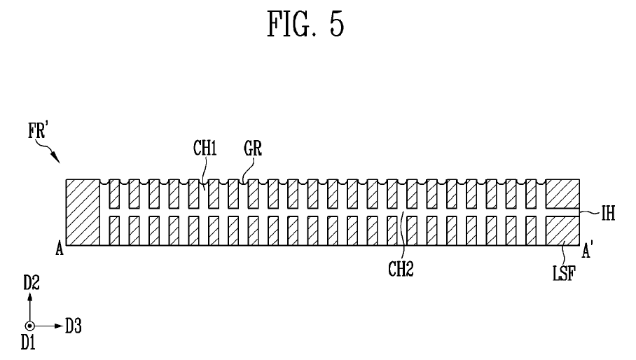

FIG. 1 is a perspective view illustrating an embodiment of a deposition mask. FIG. 2 is a plan view illustrating the deposition mask shown in FIG. 1 as viewed from above. FIG. 3 is a plan perspective view illustrating a frame of the deposition mask shown in FIG. 2 as viewed transparently. FIG. 4 is a cross-sectional view illustrating a section taken along line A-A' of FIG. 3. FIG. 5 is a cross-sectional view illustrating another embodiment of the first channel shown in FIG. 4. As used herein, the plan view of the deposition mask is a view in a thickness direction (i.e., second direction D2) of the deposition mask.

Referring to FIG. 1, a deposition mask DM may include a frame FR and a mask sheet MS.

The frame FR is a component defining an opening OP through which the deposition material passes, and the shape of the opening OP may also be defined according to the shape of the frame FR. For example, the frame FR may have a shape such as a square frame. To this end, the frame FR may include, but is not necessarily limited to, a pair of long side rods LSF, each having a first length and a pair of short side rods SSF, each having a second length shorter than the first length. For another example, the frame FR may have a form in which four sides having the same length are integrally connected.

The mask sheet MS may be arranged on the frame FR, and may include a plurality of pattern regions PA and overlapping the opening OP in a direction through which the deposition material passes (e.g., the second direction D2). Although not shown in the drawings, each of the plurality of pattern regions PA may include a plurality of pattern holes spaced apart from each other in the first direction D1 and the third direction D3 in a plane formed by the first direction D1 and the third direction D3. The deposition material emitted or vaporized from a deposition source may enter the opening OP and then pass through the pattern holes to be deposited at a target location. Here, the first direction D1 may mean a longitudinal direction of the mask sheet MS, the second direction D2 may mean a thickness direction of the mask sheet MS, and the third direction D3 may mean a latitudinal direction of the mask sheet MS.

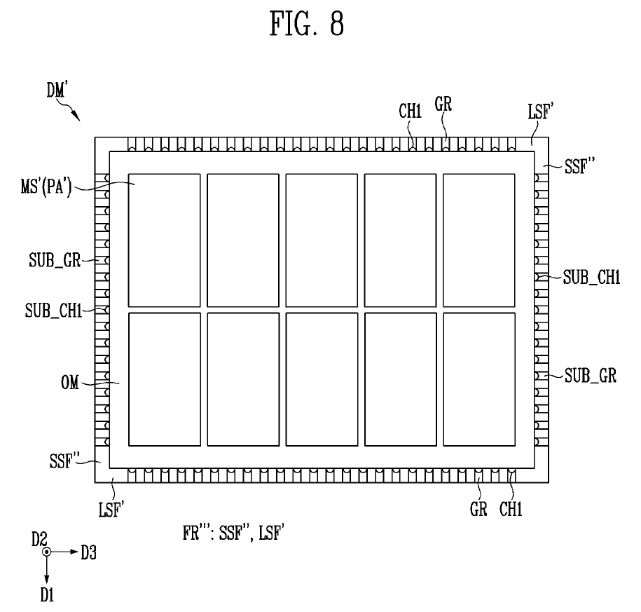

In embodiments, the mask sheet MS may have a shape in which the length in the first direction D1 is longer than the width in the third direction D3. The mask sheet MS may be composed of a plurality of first to m-th mask sheets (m is an integer of 1 or more), and may be arranged side by side in the frame FR along the third direction D3. However, the present disclosure is not necessarily limited to this embodiment, and a modified example of the mask sheet MS will be described below with reference to FIG. 8.

Referring to FIGS. 1 to 4 together, the frame FR may include a groove GR, a first channel CH1, and a second channel CH2.

The groove GR may serve as a passage through which fluid flows as a kind of empty space. To this end, the groove GR may be recessed by any depth in a direction away from the mask sheet MS (e.g., in a direction opposite to the second direction D2) at some surface of the frame FR in contact with the mask sheet MS, thereby providing a space in which fluid may flow between the frame FR and the mask sheet MS.

The cross section of the groove GR cut into a plane formed by the second direction D2 and the third direction D3 may have a semi-circular shape, but is not necessarily limited thereto. For another example, the cross section of the groove GR may have an inverted triangular shape that narrows downward. In addition, the cross-section of the groove GR may not be limited to a particular shape as long as the groove GR can provide a space in which fluid flows in the space between the mask sheet MS and the frame FR.

In embodiments, the groove GR may extend in the first direction D1. The first direction D1 may be the longitudinal direction of the mask sheet MS. In other words, the groove GR may extend in the longitudinal direction of mask sheet MS.

A portion of the groove GR may be covered by one end of the mask sheet MS, such that another portion of the grooves GR is not covered by the mask sheet MS and thus may be exposed to the outside.

The first channel CH1 may serve as an intermediate passage through which fluid flowing toward the groove GR passes. To this end, the first channel CH1 extends in a second direction D2 that intersects the first direction D1, but may communicate with the groove GR. In other words, the groove GR and the first channel CH1 may be arranged in a T-shape when viewed from the third direction D3. Further, the first channel CH1 may allow the groove GR and the second channel CH2 to communicate with each other.

Referring to FIG. 5, the first channel CH1 may penetrate the frame FR′ in the second direction D2. According to this structure, the fluid introduced from the outside may flow along the first channel CH1 to the groove GR side, while the fluid not transferred to the groove GR side may be discharged directly to the outside of the long side rod LSF′ on the opposite side of the groove GR.

The second channel CH2 may serve as an inlet passage for introducing an external fluid into the frame FR. To this end, referring to FIGS. 3 and 4, the second channel CH2 may include an injection hole IH into which an external fluid may be injected. The second channel CH2 may extend in a third direction D3 intersecting the first direction D1 and the second direction D2, and may communicate with the first channel CH1. According to this structure, the groove GR and the second channel CH2 may communicate with each other through the first channel CH1.

The fluid supplied to the injection holeIH may flow along the second channel CH2, and may flow to the first channel CH1 through a point where the first channel CH2 and the second channel CH2 communicate with each other. The fluid introduced into the first channel CH1 may then be led to the groove GR, and the cleaning solution remained between the frame FR and the mask sheet MS can be evaporated or physically pushed out of the groove GR while flowing along the groove GR.

The groove GR, the first channel CH1, and the second channel CH2 may be formed in the pair of long side rods LSF. Accordingly, a total of two injection holes IH may be formed in the frame FR.

Although not shown in the drawings, a nozzle or a blower provided in a clamper for clamping the frame FR in a cleaning process of the deposition mask DM may be detachably connected to each of the injection holes IH. One end of such a nozzle or blower may be connected to a fluid supply, and the other end may be detachably connected to each of the injection holes IH. For example, if (e.g., when) the fluid supply operates with the nozzle or the blower attached to each of the injection holes IH, the fluid may be supplied to each of the injection holes IH through the nozzle or the blower. For example, the fluid may be air, but is not necessarily limited thereto. It is preferable to use air to dry the cleaning solution remained between the mask sheet MS and the frame FR, but other fluids such as chemical solvents other than air may be used to chemically and/or physically eliminate the residual cleaning solution.

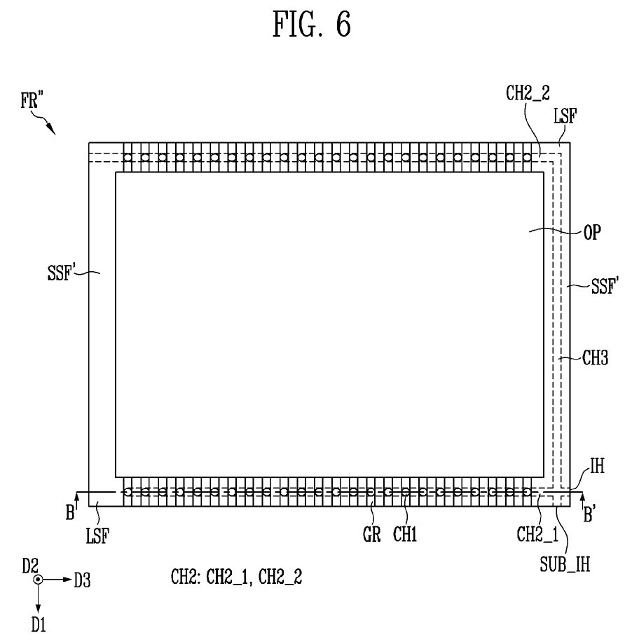

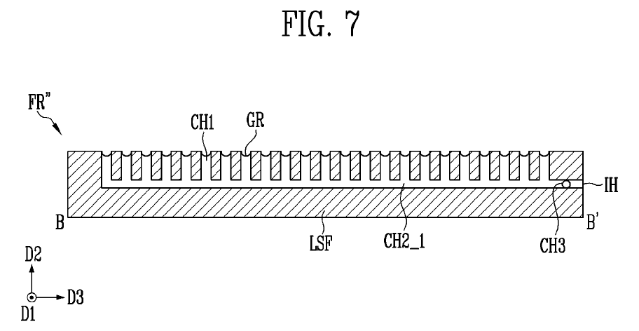

FIG. 6 is a plan perspective view illustrating another embodiment of the frame shown in FIG. 3. FIG. 7 is a cross-sectional view illustrating a section taken along line B-B' of FIG. 6.

The frame FR′′ shown in FIGS. 6 and 7 may further include a third channel CH3 compared to the frame FR shown in FIG. 3. Accordingly, components other than the third channel CH3, for example, the groove GR, the first channel CH1, and the second channel CH2 are all identically illustrated in FIGS. 3, 6, and 7, and a detailed description thereof will be omitted.

Referring to FIGS. 6 and 7, the frame FR′′ may further include a third channel CH3 extending in the first direction D1 and communicating with the second channel CH2 in at least one of the pair of short side rods SSF′.

The second channel CH2 may include a (2_1)-th channel CH2_1 formed in one of the pair of long side rods LSF and a (2_2)-th channel CH2_2 formed in the other of the pair of longer-side rods LSF.

The third channel CH3 may allow the (2_1)-th channel CH2_1 and the (2_2)-th channel CH2_2 to communicate with each other.

According to this structure, the fluid supplied to the (2_1)-th channel CH2_1 through the injection hole IH may be transferred to the (2_2)-th channel CH2_2 through the third channel CH3. In other words, instead of supplying the fluid to the two injection holes IH as shown in FIG. 3, the fluid can be supplied to the first channel CH1 and the groove GR even if the fluid is supplied only to one injection hole IH formed in the (2_1)-th channel CH2_1.

In addition, the third channel CH3 may include a sub-injection hole SUB_IH into which an external fluid may be injected, similar to the (2_1)-th channel CH2_1. According to this structure, instead of the injection hole IH formed in the (2_1)-th channel CH2_1, external air may be supplied into the frame FR′′ through the sub-injection hole SUB_IH formed in the third channel CH3. For example, the fluid injected into the sub-injection hole SUB_IH may be transferred to the (2_1)-th channel CH2_1 and the (2_2)-th channel CH2_2 in communication with the third channel CH3, and then also to the first channel CH1 and the groove GR.

In addition, external fluid may be injected into both the injection hole IH and the sub-injection hole SUB_IH at the same time. Even in this case, the fluid injected into the (2_1)-th channel CH2_1 and the third channel CH3 may sequentially flow through the (2_2)-th channel CH2_2, the first channel CH1, and the groove GR, and then be discharged to the outside again.

As such, the residual cleaning solution may be effectively and swiftly eliminated, thereby extending the lifespan of the deposition mask DM by forming a space such as the groove GR through which a fluid may flow is formed in a region where the frame FR, FR’, FR’’ and the mask sheet MS come into contact, and passages such as the first to third channels CH1 to CH3 are provided to transfer an external fluid into the groove GR.

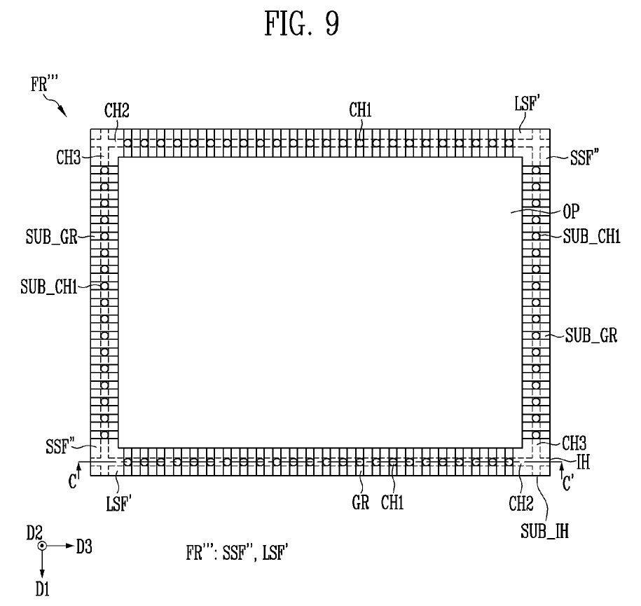

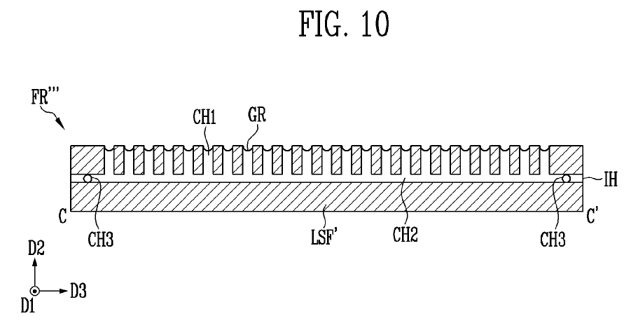

FIG. 8 is a plan view illustrating another embodiment of the deposition mask shown in FIG. 2. FIG. 9 is a plan perspective view illustrating the frame of the deposition mask shown in FIG. 8 as viewed transparently. FIG. 10 is a cross-sectional view illustrating a section taken along line C-C' of FIG. 9.

The deposition mask DM′ shown in FIGS. 8 to 10 may have a different shape and arrangement of the mask sheet MS′, a different arrangement of the second channel CH2 and the third channel CH3, and may further include a sub-groove SUB_GR and a sub-first channel SUB_CH1 compared to the deposition mask DM shown in FIGS. 2 to 4. Accordingly, the remaining components except for the mask sheet MS′, the second channel CH2, the third channel CH3, the sub-groove SUB_GR, and the sub-first channel SUB_CH1, for example, the groove GR and the first channel CH1, are all identically illustrated in FIGS. 2 to 4 and FIGS. 8 to 10, and a detailed description thereof will be omitted.

Referring to FIGS. 8 and 9, the mask sheet MS′ may be arranged on the frame FR′′′ in a manner similar to the mask sheet MS shown in FIG. 2, and a pattern region PA′ overlapping the opening OP may be formed in a direction (e.g., second direction D2) through which the deposition material passes.

However, the mask sheet MS′ may be arranged on the frame FR′′′ through the open mask OM. The open mask OM may include sub-openings corresponding to the shape and number of mask sheet MS′. The mask sheet MS′ may be coupled to the open mask OM in a state of being pulled in the first direction and a direction opposite to the first direction D1, and in the third direction and a direction opposite from the third direction D3, respectively.

In the above paragraph, the mask sheet MS′ and the open mask OM are separately described for convenience of description, but the structure in which the mask sheet MS' and the open mask OM are combined eventually means the same structure as the mask sheet MS shown in FIG. 2. The reason for this is that, similarly to the mask sheet MS of FIG. 2 being arranged on the frame FR, a structure in which the mask sheet MS′ and the open mask OM are combined is also arranged as an integral structure on the frame FR′′′. Accordingly, for ease of description hereinafter, the mask sheet MS′ may refer to a structure in which the mask sheet MS' and the open mask OM are combined.

Referring to FIG. 8, one side of the mask sheet MS′ and the other side of the mask sheet MS′ opposite to the one side in the third direction D3 may overlap the frame FR′′′ in the second direction D2. According to this structure, since one side and the other side of the mask sheet MS′ are also in contact with the frame FR′′′, this means that the cleaning solution may remain in the region in contact with the framework FR′′′ on one side and on the other side of mask sheet MS′.

In order to remove the cleaning solution remained in the region where one side and the other side of the mask sheet MS′ and the frame FR′′′ are in contact with each other as described above, the frame FR′’′ may further include a sub-groove SUB_GR extending in the third direction D3.

The sub-groove SUB_GR, like the groove GR, may also serve as a passage through which fluid flows as a kind of empty space. The sub-groove SUB_GR may be formed in the pair of short side rods SSF′′, except that it extends in the third direction D3, all remaining structural features may be substantially the same as the groove GR. For example, the sub-groove SUB_GR, like the groove GR, can also be recessed by any depth in a direction away from the mask sheet MS′ (e.g., in a direction opposite to the second direction D2) from a portion of the surface of the frame FR′′′ that contacts the mask sheet MS’ (precisely, the top surface of the pair of short side rods SSF′′), thereby providing a space in which fluid can flow between the frame FR′,′′ and the mask sheet MS. In addition, the shape of the sub-groove SUB_GR may also be a semi-circle or an inverted triangle like the groove GR, but is not limited thereto, as described above.

A portion of the sub-groove SUB_GR may be covered by one side and the other side of the mask sheet MS′, and another portion of the sub-groove SUB_GR may be exposed to the outside.

Referring to FIGS. 9 and 10, the frame FR′′′ may further include a sub-first channel SUB_CH1.

The sub-first channel SUB_CH1, like the first channel CH1, may serve as an intermediate passage through which the fluid flowing towards the sub-groove SUB_GR passes. To this end, the sub-first channel SUB_CH1 may extend in the second direction D2 and communicate with the sub-groove SUB_GR. In other words, the sub-groove SUB_GR and the sub-first channel SUB_CH1 may be arranged in a T-shape when viewed from the first direction D1. In addition, the sub-first channel SUB_CH1 may allow the sub-groove SUB_GR and the third channel CH3 to communicate with each other.

The second channel CH2 may extend in the third direction D3, with two such channels CH2 may be formed to penetrate each of the pair of long side rods LSF′. The second channel CH2 may include an injection hole IH capable of injecting an external fluid, and in FIG. 9, one injection hole IH is shown at the lower right, but is not necessarily limited thereto. Since the second channel CH2 may penetrate the pair of the long side rods LSF′, at least one of holes formed on the left and right sides in the third direction D3, respectively, may be utilized as the injection hole IH. In other words, at least one of a total of four holes shown in the upper left and lower left, and the upper right and lower right, respectively, of the frame FR′′′ shown in FIG. 9 may be utilized as the injection hole IH. Then, the fluid injected into the frame FR′′′ through the holes not used as the injection hole IH among the four holes in total may be discharged to the outside again after removing the cleaning solution remained in the deposition mask DM′.

The third channel CH3 may extend in the first direction D1, with two such third channels CH3 may be formed to penetrate each of the pair of short side rods SSF′′. The third channel CH3 may include a sub-injection hole SUB_IH capable of injecting an external fluid, and in FIG. 9, one sub-injection hole SUB_ IH is shown at the lower right, but is not necessarily limited thereto. Since the third channel CH3 penetrates the pair of the short side rods SSF′′, at least one of holes formed on the upper and lower left sides in the first direction D1, respectively, may be utilized as the sub-injection hole SUB_IH. In other words, at least one of a total of four holes shown in the upper left and lower left, and the upper right and lower right, respectively, of the frame FR′′′ shown in FIG. 9 may be utilized as the sub-injection hole SUB_IH. Then, the fluid injected into the frame FR′′′ through the holes that are not utilized as the sub-injection hole SUB_IH among the four holes in total can be discharged to the outside again after removing the cleaning solution remained in the deposition mask DM′.

The second channel CH2 and the third channel CH3 may communicate with each other. According to this structure, a portion of the fluid injected through at least one of the injection hole IH and the sub-injection hole SUB_IH may sequentially flow through the second channel CH2, the first channel CH1, and the groove GR, and another portion may sequentially flow through a third channel CH3, the sub-first channel SUB_CH1, and the sub-groove SUB_GR. If (e.g., when) the external fluid is injected only into the injection hole IH, some of the fluid may flow sequentially through the second channel CH2, the first channel CH1, and the groove GR, and others may flow sequentially through a second channel CH2, a third channel CH3, the sub-first channel SUB_CH1, and the sub-groove SUB_GR, and may also be transferred to the opposite second channel CH2 in communication with the third channel CH3 to flow sequentially through the opposite first channel CH1 and the groove GR.

As such, the residual cleaning solution may be effectively and swiftly eliminated, thereby extending the lifespan of the deposition mask DM’ by forming a space such as the groove GR and the sub-groove SUB_GR, through which a fluid may flow is formed in a region where the frame FR′′′ and the mask sheet MS′ come into contact, and passages such as the first to third channels CH1 to CH3 and the sub-first channel SUB_CH1 are provided to transfer an external fluid to the groove GR or the sub-grooves SUB_GR.

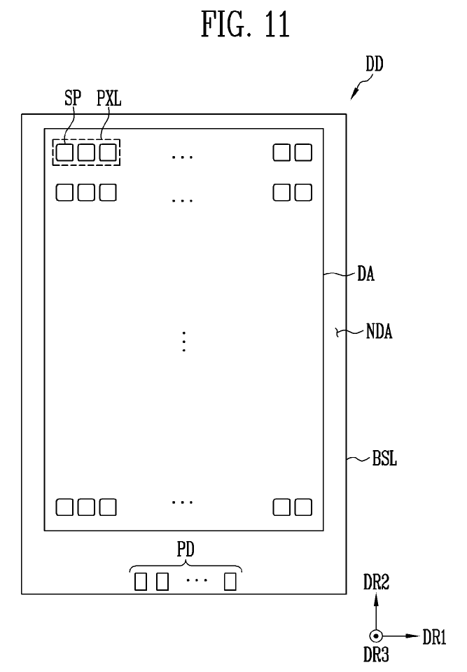

Hereinafter, the display device DD will be described with reference to FIGS. 11 to 13.

The display device DD illustrated in FIGS. 11 to 13 may be a display device DD manufactured using the deposition mask DM and DM′ described above.

FIG. 11 is a plan view illustrating an embodiment of a display device.

Referring to FIG. 11, a display device DD (or a display panel) may include a display area DA and a non-display area NDA. The display device DD may display an image through the display area DA. The non-display area NDA may be arranged around the display area DA.

The display device DD may include a substrate SUB, sub-pixels SP, and/or pads PD.

The sub-pixels SP may be arranged in the display area DA on the substrate SUB. The sub-pixels SP may be arranged in a matrix form along the first direction DR1 and the second direction DR2 intersecting the first direction DR1, but are not necessarily limited thereto. For example, the sub-pixels SP may be arranged in a zigzag shape along the first direction DR1 and the second direction DR2. Alternatively, the sub-pixels SP may be arranged in the form of a pentile (PENTILE^{TM}). Here, the first direction DR1 may be a row direction, and the second direction DR2 may be a column direction. Two or more of the sub-pixels SP may constitute one pixel PXL.

A component for controlling the sub-pixels SP may be arranged in the non-display area NDA on the substrate SUB. For example, wirings connected to the sub-pixels SP, such as gate lines and data lines, may be arranged in the non-display area NDA.

Pads PD may be arranged in the non-display area NDA on the substrate SUB. The pads PD may be electrically connected to the sub-pixels SP through wirings. For example, the pads PD may be connected to the sub-pixels SP via data lines.

Voltages and signals required for operation of components included in the display device DD may be provided from the driver integrated circuit through the pads PD. For example, the data lines may be connected to the driver integrated circuit via pads PD. Power voltages may also be received from the driver integrated circuit via pads PD.

In embodiments, a conductive adhesive member such as an anisotropic conductive film may be used to electrically connect the circuit board to the pads PD. In this case, the circuit board may be a flexible circuit board or a flexible film having a flexible material. The driver integrated circuit may be mounted on a circuit board and electrically connected to the pads PD.

In embodiments, the display area DA may have various shapes. The display area DA may have the shape of a closed loop including straight and/or curved sides. For example, the display area DA may have shapes such as a polygon, a circle, a semicircle, and an ellipse.

In embodiments, the display device DD may have a flat display surface. Alternatively, the display device DD may have an at least partially round display surface. The display device DD may be bendable, foldable, or rollable. In such cases, the display device DD and/or the substrate SUB may include materials having a flexible property.

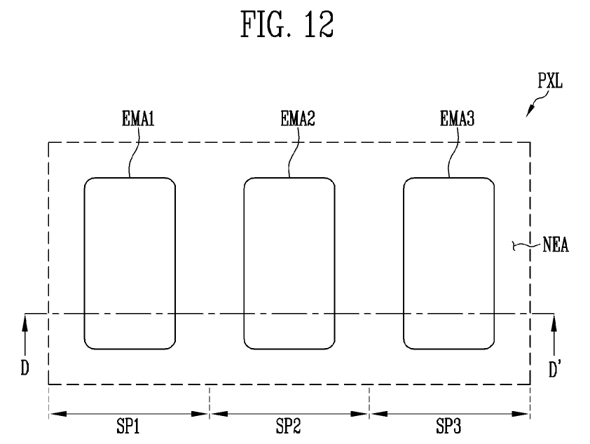

FIG. 12 is a plan view illustrating an embodiment of a sub-pixel shown in FIG. 11.

Referring to FIG. 12, the pixel PXL may include first to third sub-pixels SP1 to SP3 arranged in the first direction DR1.

The first sub-pixel SP1 may include a first light emitting area EMA1 and a non-light emitting area NEA around the first light emitting area EMA1. The second sub-pixel SP2 may include a second light emitting area EMA2 and a non-light emitting area NEA around the second light emitting area EMA2. The third sub-pixel SP3 may include a third light emitting area EMA3 and a non-light emitting area NEA around the third light emitting area EMA3.

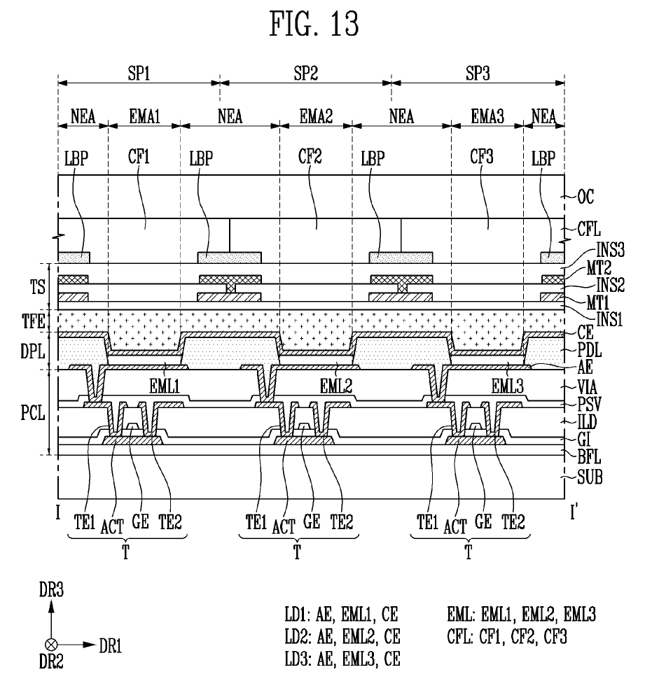

The first light emitting area EMA1 may be an area in which light is emitted from the first light emitting layer EML1 (see FIG. 13) of the first sub-pixel SP1. The second light emitting area EMA2 may be an area in which light is emitted from the second light emitting layer EML2 (see FIG. 13) of the second sub-pixel SP2. The third light emitting region EMA3 may be a region where light is emitted from the third light emitting layer EML3 (see FIG. 13) of the third sub-pixel SP3.

FIG. 13 is a cross-sectional view illustrating a section taken along line D-D' of FIG. 12.

Referring to FIG. 13, each of the first to third sub-pixels SP1 to SP3 includes a light emitting area EMA1, EMA2, and EMA3, and a non-light emitting area NEA may be positioned between the light emitting areas EMA1, EMA2, and EMA3 of the first to third sub-pixels SP1 to SP3.

Each of the first to third sub-pixels SP1 to SP3 may include a pixel circuit layer PCL, a display element layer DPL, and/or a thin film encapsulation layer TFE sequentially arranged on the substrate SUB.

The substrate SUB may form a base surface. The substrate SUB may include a transparent insulating material to enable transmission of light. The substrate SUB may be a rigid substrate or a flexible substrate. The rigid substrate may be, for example, one of a glass substrate, a quartz substrate, a glass ceramic substrate, and a crystalline glass substrate. The flexible substrate may be one of a film substrate including a polymer organic material and a plastic substrate. For example, the flexible substrate may include, but is not necessarily limited to, at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate. For example, the substrate SUB may be a substrate including silicon. In embodiments, the display device DD may be an OLED on Silicon (OLEDoS) display device including a display panel formed on a silicon substrate.

The pixel circuit layer PCL may include a buffer layer BFL, a gate insulating layer GI, an interlayer-insulating layer ILD, a passivation layer PSV, and/or a via-layer VIA sequentially stacked on the substrate SUB along the third direction DR3.

The buffer layer BFL may be an inorganic insulating film including an inorganic material. The buffer layer BFL may include at least one of silicon nitride (SiNx), silicon oxide (SiOx), silicon oxynitride (SiOxNy), and a metal oxide such as aluminum oxide (AlOx). The buffer layer BFL may be provided as a single layer, but may be provided as at least a double layer or more. When the buffer layer BFL is provided as multiple layers, each layer may be formed of the same material or different materials. The buffer layer BFL may be omitted depending on the material of the substrate SUB, process conditions, and the like.

A transistor T may be arranged on the buffer layer BFL. The transistor T may include an active pattern ACT, a gate electrode GE, a first transistor electrode TE1, and/or a second transistor electrode TE2.

The active pattern ACT may be arranged on the buffer layer BFL. The active pattern ACT may include a polysilicon semiconductor. For example, the active pattern ACT may be formed via a low temperature polysilicon process. However, the present disclosure is not necessarily limited thereto, and the active pattern ACT may be formed of an oxide semiconductor, a metal oxide semiconductor, or the like.

The active pattern ACT may include a channel region, a first contact region connected to one end of the channel region, and a second contact region connected to the other end of the channel regions, respectively. The channel region, the first contact region, and the second contact region may be formed of a semiconductor layer that is not doped with impurities or is doped with impurities. For example, the first contact region and the second contact region may include a semiconductor layer doped with impurities, and the channel region may include a semiconducting layer not doped with impurities. As the impurity, for example, a p-type impurity may be used, but is not necessarily limited thereto. One of the first and second contact regions may be a source region, and the other may be a drain region.

A gate insulating layer GI may be arranged on the active pattern ACT. The gate insulating layer GI may be an inorganic film (or an inorganic insulating film) including an inorganic material. For example, the gate insulating layer GI may include at least one of silicon nitride (SiNx), silicon oxide (SiOx), silicon oxynitride (SiOxNy), and a metal oxide such as aluminum oxide (AlOx). However, the material of the gate insulating layer GI is not necessarily limited to the above-described embodiments. In embodiments, the gate insulating layer GI may be formed of an organic film (or an organic insulating film) including an organic material. The gate insulating layer GI may be provided as a single layer, but may be provided as at least a double layer or more.

The gate electrode GE may be arranged on the gate insulating layer GI. The gate electrode GE may overlap the channel region of the active pattern ACT. The gate electrode GE may be formed of a single layer of a single layer selected from the group consisting of copper (Cu), molybdenum (Mo), tungsten (W), aluminum neodymium (AlNd), titanium (Ti), aluminum (Al), silver (Ag) and alloys thereof, or a double layer or multilayer structure of a low-resistance material molybdenium (Mo), titanium (Ty), copper (Cu) aluminum (Al) or silver (Ag) to reduce wiring resistance.

An interlayer-insulating layer ILD may be arranged on the gate electrode GE. The interlayer-insulating layer ILD may include the same material as the gate insulating layer GI or may include one or more materials selected from the materials illustrated as constituent materials of the gate insulating layer GI.

The first transistor electrode TE1 and the second transistor electrode TE2 may be arranged on the interlayer-insulating layer ILD.

The first transistor electrode TE1 may be in contact with the first contact region of the active pattern ACT through a contact hole penetrating the interlayer-insulating layer ILD and the gate insulating layer GI. If (e.g., when) the first contact region is a source region, the first transistor electrode TE1 may be a first source electrode.

The second transistor electrode TE2 may be in contact with the second contact region at the other end of the active pattern ACT through a contact hole penetrating the interlayer-insulating layer ILD and the gate insulating layer GI. If (e.g., when) the second contact region is a drain region, the second transistor electrode TE2 may be a second drain electrode.

Each of the first transistor electrode TE1 and the second transistor electrode TE2 may include the same material as the gate electrode GE or may include one or more materials selected from the materials illustrated as constituent materials of the gate electrode GE.

A passivation layer PSV may be arranged on the first transistor electrode TE1 and the transistor electrodes TE2. The passivation layer PSV (e.g., a protective layer) may be an inorganic film (or an inorganic insulating film) including an inorganic material or an organic film (or an organic insulating film) including an organic material. The inorganic film may include, for example, at least one of metal oxides such as silicon oxide (SiOx), silicon nitride (SiNx), silicon oxynitride (SiOxNy), and aluminum oxide (AlOx). The organic film may include, for example, at least one of an acrylic resin, an epoxy resin, a phenolic resin, a polyamide resin, a polyimide resin, an unsaturated polyester resin, a polyphenylene ethers resin, a polyphenylene sulfides resin, and a benzocyclobutene resin.

In embodiments, the passivation layer PSV may include the same material as the interlayer-insulating layer ILD, but is not necessarily limited thereto. The passivation layer PSV may be provided as a single layer, but may be provided as at least a double layer or more.

A via-layer VIA may be arranged on the passivation layer PSV. The via-layer VIA may include the same material as the passivation layer PSV or may include one or more materials selected from the materials illustrated as constituent materials of the passivation layer PSV. In embodiments, the via-layer VIA may be an organic film made of an organic material.

A display element layer DPL may be arranged on the pixel circuit layer PCL. The display element layer DPL may include a light emitting element LD that emits light. The first to third sub-pixels SP1 to SP3 may include first to third light emitting elements LD1 to LD3, respectively.

The first light emitting element LD1 may include an anode electrode AE, a first light emitting layer EML1, and a cathode electrode CE. The second light emitting element LD2 may include an anode electrode AE, a second light emitting layer EML2, and a cathode electrode CE. The third light emitting element LD3 may include an anode electrode AE, the third light emitting elements LD3 may include the anode electrode AE and the cathode electrode CE. For example, the first to third light emitting elements LD1 to LD3 may be front-emitting organic light emitting elements.

The anode electrodes AE of the sub-pixels SP are arranged in the light emitting regions EMA1, EMA2, and EMA3, and may be spaced apart from each other. The anode electrode AE of each of the sub-pixels SP may be electrically connected to the first transistor electrode TE1 of each sub-pixel SP through a contact hole passing through the via-layer VIA and the passivation layer PSV, respectively.

A bank PDL may be arranged on the anode electrode AE. The bank PDL may define (or partition) the light emitting regions EMA1, EMA2, and EMA3 of each sub-pixel SP. The bank PDL may include an opening that partially exposes the anode electrode AE of each sub-pixel SP.

The bank PDL may be an organic insulating layer made of an organic material. The organic material may include, but is not necessarily limited to, an acryl resin, an epoxy resin, a phenolic resin, a polyamide resin, a polyimide resin, and the like. For example, the bank PDL may be an inorganic insulating layer made of an inorganic material.

In embodiments, the bank PDL may include a light absorbing material, or a light absorbing agent may be applied to serve to absorb light introduced from the outside. For example, the bank PDL may include a carbon-based black pigment. However, the present disclosure is not necessarily limited thereto, and the bank PDL may include an opaque metal material such as chromium (Cr), molybdenum (Mo), an alloy of molybdenium (Mo) and titanium (Ti) (MoTi), tungsten (W), vanadium (V), niobium (Nb), tantalum (Ta), manganese (Mn), cobalt (Co), or nickel (Ni) having a high light absorption rate.

The light emitting layer EML of each sub-pixel SP may be arranged on the anode electrode AE exposed by the bank PDL. The cathode electrode CE may be arranged on the light emitting layer EML. The cathode electrode CE may be arranged throughout the first to third sub-pixels SP1 to SP3. For example, the cathode electrode CE may be provided as a common electrode, but is not necessarily limited thereto.

The cathode electrode CE may be formed of a metal layer such as Ag (silver), Mg (magnesium), Al (aluminum), Pt (platinum), Pd (palladium), Au (gold), Ni (nickel), Nd (neodymium), Ir (iridium), Cr (chromium), or an alloy thereof, and/or a transparent conductive layer such as indium tin oxide (ITO), indium zinc oxide (IZO), zinc oxide (ZnO), or indium tin zinc oxide (ITZO). In embodiments, the cathode electrode CE may consist of multiple layers, such as a double layer or more, including a thin metal layer, for example, a triple layer of ITO/Ag/ITO.

A thin film encapsulation layer TFE may be arranged on the display element layer DPL. The thin film encapsulation layer TFE may have a single layer structure or a multilayer structure. The thin film encapsulation layer TFE may include an insulating layer covering the light emitting element LD. The thin film encapsulation layer TFE may include at least one inorganic film and at least one organic film. For example, the thin film encapsulation layer TFE may have a structure in which an inorganic film and an organic film are alternately stacked. For example, the thin film encapsulation layer TFE may include a first inorganic film, an organic film arranged on the first inorganic film, and a second inorganic film arranged on the organic film.

A sensing layer TS may be arranged on the thin film encapsulation layer TFE. The sensing layer TS may include a first insulating layer INS1, a first conductive layer MT1, a second insulating layer INS2, a second conductive layer MT2, and/or a third insulating layer INS3.

The first insulating layer INS1 may be arranged on the thin film encapsulation layer TFE. The first insulating layer INS1 may be an inorganic insulating layer including an inorganic material. The inorganic insulating layer may include an inorganic insulating material such as silicon oxide (SiOx), silicon nitride (SiNx), silicon oxynitride (SiOxNy), aluminum oxide (AlxOy), titanium oxide (TiOx), tantalum oxide (TaxOy), hafnium oxide (HfOx), zinc oxide (ZnOx), or the like. In embodiments, the first insulating layer INS1 may be omitted or configured as the uppermost layer of the thin film encapsulation layer TFE.

The first conductive layer MT1 may be arranged on the first insulating layer INS1. The first conductive layer MT1 may be partially opened so as not to overlap the light emitting element LD of each sub-pixel SP. For example, the first conductive layer MT1 may be arranged to overlap the non-light emitting area NEA around the light emitting areas EMA1, EMA2, and EMA3.

The first conductive layer MT1 may include a metal layer or a transparent conductive layer. For example, the metal layer may include molybdenum, titanium, copper, aluminum, and alloys thereof. The transparent conductive layer may include, but is not necessarily limited to, one of indium tin oxide (ITO), indium zinc oxide (IZO), zinc oxide (ZnO), indium tin zinc oxide (ITZO), PEDOT, and metal nanowires. The first conductive layer MT1 may form a connection electrode connecting the sensing electrodes.

The second insulating layer INS2 may be arranged on the first conductive layer MT1. The second insulating layer INS2 may include the same material as the first insulating layer INS1 described above, or may include one or more materials selected from materials exemplified as constituent materials of the first insulating layer INS1.

The second conductive layer MT2 may be arranged on the second insulating layer INS2. The second conductive layer MT2 may be partially opened so as not to overlap the light emitting element LD of each sub-pixel SP. For example, the second conductive layer MT2 may be arranged to overlap the non-light emitting area NEA around the light emitting areas EMA1, EMA2, and EMA3.

The second conductive layer MT2 may include the same material as the above-described first conductive layer MT1, or may include one or more materials selected from materials exemplified as constituent materials of the first conductive layer MT1.

The second conductive layer MT2 may be electrically connected to the first conductive layer MT1 through a contact hole penetrating the second insulating layer INS2. The second conductive layer MT2 may form sensing electrodes.

A third insulating layer INS3 may be arranged on the second conductive layer MT2. The third insulating layer INS3 may be an organic insulating layer including an organic material, but is not necessarily limited thereto. For example, the third insulating layer INS3 may be formed of an inorganic film or may have a structure in which an organic film and an inorganic film are alternately stacked.

A light blocking layer LBP may be arranged on the display element layer DPL, the thin film encapsulation layer TFE, and/or the sensing layer TS. The light blocking layer LBP may include an opening overlapping the light emitting element LD. For example, the light blocking layer LBP may be arranged to overlap the non-light emitting area NEA around the light emitting regions EMA1, EMA2, and EMA3.

The light blocking layer LBP may include a light blocking material to prevent light leakage and color mixing defects. For example, the light blocking layer LBP may include, but is not necessarily limited to, a black matrix. In embodiments, the light blocking layer LBP may include carbon black (CB) and/or titanium black (TiBK).

A color filter layer CFL may be arranged on the light blocking layer LBP. The color filter layer CFL may include color filters CF1 to CF3 that match the color of each sub-pixel SP. By arranging the color filters CF1 to CF3 corresponding to the colors of the first to third sub-pixels SP1 to SP3, a full-color image may be displayed.

The color filter layer CFL may include a first color filter CF1 arranged in the first sub-pixel SP1 to selectively transmit light emitted from the first sub-pixel SP1, a second color filter CF2 arranged in the second sub-pixel SP2 to selectively transmit light emission from the second sub-pixel SP2, and a third color filter CF3 arranged in the third sub-pixel SP3 to selectively transmit light emitting from the third sub-pixel SP3.

In embodiments, the first color filter CF1, the second color filter CF2, and the third color filter CF3 may be, but are not necessarily limited to, a red color filter, a green color filter, and a blue color filter, respectively.

The first color filter CF1 may include a color filter material that selectively transmits light of a first color (or red). For example, when the first sub-pixel SP1 is a red sub-pixel, the first color filter CF1 may include a red color filter material.

The second color filter CF2 may include a color filter material that selectively transmits light of a second color (or green). For example, when the second sub-pixel SP2 is a green sub-pixel, the second color filter CF2 may include a green color filter material.

The third color filter CF3 may include a color filter material that selectively transmits light of a third color (or blue). For example, when the third sub-pixel SP3 is a blue sub-pixel, the third color filter CF3 may include a blue color filter material.

An overcoat layer OC may be arranged on the color filter layer CFL. The overcoat layer OC may include a variety of materials suitable for protecting the underlying layers from foreign materials such as dust, moisture, and the like. In embodiments, the overcoat layer OC may include at least one of an inorganic insulating film and an organic insulating film. For example, the overcoat layer OC may include, but is not necessarily limited to, epoxy.

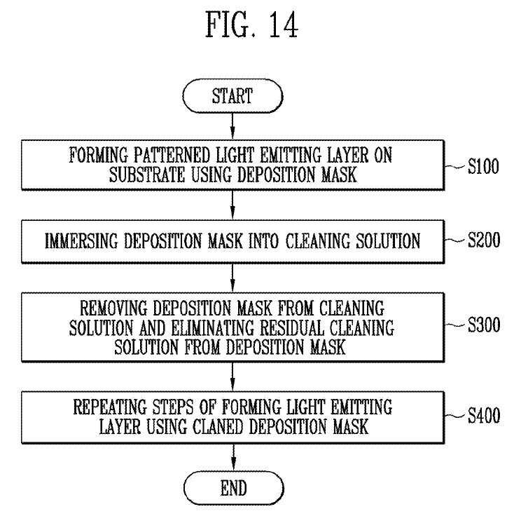

Hereinafter, a method of manufacturing the display device DD will be described with reference to FIG. 14.

FIG. 14 is a flowchart illustrating an embodiment of a method for manufacturing a display device.

The method of manufacturing the display device DD illustrated in FIG. 14 may be a method of depositing the first to third light emitting layers (EML1 to EML3 in FIG. 13) of the display device DD described with reference to FIGS. 11 to 13 using the deposition masks DM and DM′ described with reference to FIG. 1 to FIG. 10.

Referring to FIG. 14, a method of manufacturing a display device DD may include a step S100 of forming a patterned light emitting layer on a substrate by using a deposition mask DM, DM′, a step S200 of immersing the deposition mask DM, DM′ into a cleaning solution, a step S300 of removing the deposition mask DM, DM’ from the cleaning solution and eliminating the residual cleaning solution from the deposition mask DM, DM’, and a step S400 of repeating the steps of forming the light emitting layer by reusing the deposition mask DM, DM′.

The step S300 may include a step of injecting a fluid into the second channel CH2. As described above, the second channel CH2 may include an injection hole IH, and the external fluid injected into the second channel CH2, through the injection hole IH may flow sequentially into the second channel, the first channel CH1, and the groove GR to dry the deposition masks DM, DM′, or physically push the residual cleaning solution to the outside.

In addition, the step S300 may further include a step of injecting a fluid into the third channel CH3. As described above, the third channel CH3 may include a sub-injection hole SUB_IH, and the external fluid injected into the third channel CH3, through the sub-injection hole SUB_ IH, may flow into the (2_1)-th channel CH2_1 and the (2_2)-th channel CH2_2. In addition, some of the fluid flowing into the third channel CH3 may flow sequentially in the first channel CH1 and the groove GR via the second channel CH2, and other parts may flow sequentially in a sub-first channel SUB_CH1 and a sub-groove SUB_GR via the third channel CH3, thereby drying the deposition mask DM, DM′ or physically pushing the residual cleaning solution to the outside.

As described above, according to the method for manufacturing the display device DD using the deposition mask DM and DM′, the residual cleaning solution remained in the deposition mask DM, DM′ can be effectively removed, and the time required for cleaning can be shortened. As a result, the lifetime of the deposition mask DM, DM′ repeatedly used for vapor deposition of the light emitting layers EML1 to EML3 of the display device DD can be increased, and the yield of the display device DD can be increased.

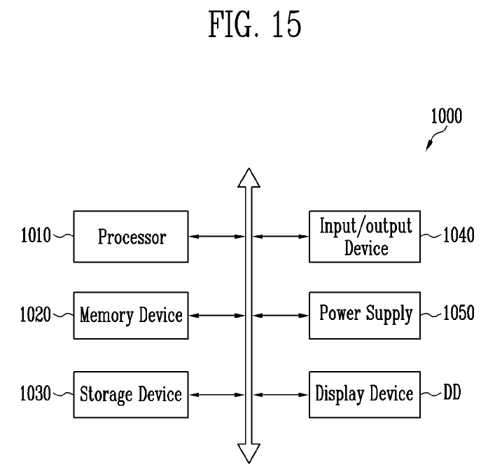

Hereinafter, an electronic device 1000 including the display device DD manufactured according to the above-described method for manufacturing the display device DD will be described with reference to FIGS. 15 to 17.

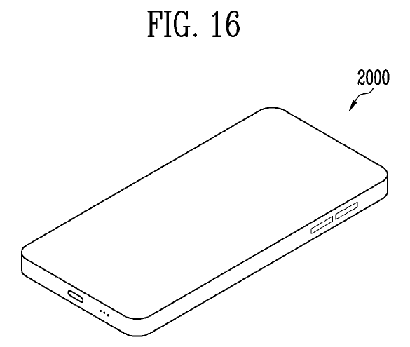

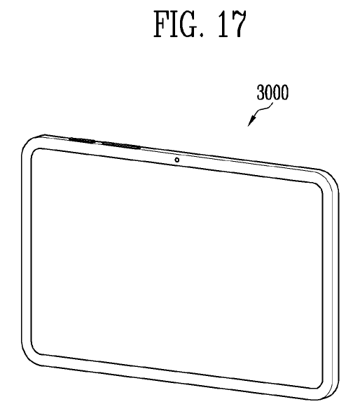

FIG. 15 is a block diagram illustrating an embodiment of an electronic device including the display device shown in FIG. 11. FIG. 16 is a perspective view illustrating an example of a smartphone implemented using the electronic device shown in FIG. 15. FIG. 17 is a perspective view illustrating an example of a tablet computer implemented using the electronic device shown in FIG. 15.

Referring to FIG. 15, the electronic device 1000 may include a processor 1010, a memory device 1020, a storage device 1030, an input/output device 1040, a power supply device 1050, and a display device DD.

The processor 1010 may perform various tasks and calculations. In embodiments, processor 1010 may include an application processor, a graphics processing unit, a microprocessor, a central processing unit (CPU), and the like. The processor 1010 may be connected to other components of the electronic device 1000 through a bus system. In embodiments, the bus system may include a peripheral component interconnect (PCI) bus. The processor 1010 may provide an input image data to the display device DD. Hence, the display device DD may display an image based on the input image data provided from the processor 1010.

The memory device 1020 may be provided as a working memory and/or a buffer memory of the electronic device 1000 and/or the processor 1010. In embodiments, memory device 1020 may include volatile memory devices such as dynamic random access memory (DRAM), static random access memory (SRAM), mobile DRAM, and the like.

The storage device 1030 may store data in response to control of the processor 1010. The storage device 1030 may include a nonvolatile storage medium that maintains data even when the power of the electronic device 1000 is cut off. In embodiments, storage device 1030 may include a solid state drive (SSD), a hard disk drive (HDD), or the like.

The input/output device 1040 may include user input devices such as a keyboard, keypad, touchpad, touchscreen, mouse, and the like, and output devices such as a speaker, printer, and the like.

The power supply device 1050 may supply power required for the operation of the electronic device 1000. For example, the power supply device 1050 may be a power management integrated circuit (PMIC). For example, the power supply device 1050 may include a battery.

The display device DD may display an image in response to the control of the processor 1010. The display device DD may be connected to other components of the electronic device 1000 via a bus system and/or other communication link. The display device DD may be implemented as the display device DD of FIG. 13. Display device DD may display an image on pixels PXL, and each of pixels PXL may be configured as shown in FIG. 12 according to an embodiment.

Although specific embodiments and applications have been described herein, it goes without saying that other embodiments and modifications may be derived from the above description. Accordingly, the present disclosure is not limited to these embodiments, but may extend to the claims, various obvious modifications, and equivalents set forth below.

What is claimed is:

1. A deposition mask, comprising:
a frame in which an opening through which a deposition material passes is defined; and
a mask sheet arranged on the frame, including at least one pattern region overlapping the opening in a direction through which the deposition material passes is formed,
wherein the frame includes a groove extending in a first direction, a first channel extending in a second direction intersecting the first direction and communicating with the groove, and a second channel extending in a third direction intersecting the first and second directions and communicating with the first channel,
wherein the first channel communicates the groove and the second channel with each other, and
wherein the second channel includes an injection hole into which an external fluid is injected.

2. The deposition mask according to claim 1, wherein the first direction is a longitudinal direction of the mask sheet,
wherein the second direction is a thickness direction of the mask sheet, and
wherein the third direction is a latitudinal direction of the mask sheet.

3. The deposition mask according to claim 1, wherein a portion of the groove is covered by one end of the mask sheet, and
wherein another portion of the groove is exposed to an outside.

4. The deposition mask according to claim 1, wherein the frame includes:
a pair of long side rods, each having a first length; and
a pair of short side rods, each having a second length shorter than the first length,
wherein the groove, the first channel, and the second channel are formed in the pair of long side rods.

5. The deposition mask according to claim 4, wherein the frame further includes a third channel extending in the first direction in at least one of the pair of short side rods and in communication with the second channel.

6. The deposition mask according to claim 5, wherein the second channel includes:
a (2_1)-th channel formed in any one of the pair of long side rods; and
a (2_2)-th channel formed in another one of the pair of long side rods,
wherein the third channel communicates the (2_1)-th channel and the (2_2)-th channel with each other.

7. The deposition mask according to claim 5, wherein the third channel includes a sub-injection hole into which an external fluid is injectable.

8. The deposition mask according to claim 1, wherein one side of the mask sheet and an opposite side of the mask sheet opposite to the one side in the third direction overlap the frame in the second direction, and
wherein the frame further includes a sub-groove extending in the third direction.

9. The deposition mask according to claim 8, wherein a portion of the sub-groove is covered by the one side or the opposite side of the mask sheet, and
wherein another portion of the sub-groove is exposed to an outside.

10. The deposition mask according to claim 8, wherein the frame further includes:
a sub-first channel communicating with the sub-groove and extending in the second direction; and
a third channel communicating with the sub-first channel and extending in the first direction,
wherein the sub-first channel communicates the sub-groove and the third channel with each other.

11. The deposition mask according to claim 10, wherein the third channel includes a sub-injection hole into which an external fluid is injectable.

12. The deposition mask according to claim 10, wherein the second channel and the third channel are in communication with each other.

13. The deposition mask according to claim 1, wherein the groove includes first to n-th grooves spaced apart from each other along the third direction, and n is an integer of 1 or more,
wherein at least one of the first to n-th grooves is covered by one end of the mask sheet, and
wherein remaining grooves of the first to n-th grooves other than the at least one of the first to n-th grooves are exposed to an outside.

14. A method of manufacturing a display device, comprising:
forming a patterned light emitting layer on a substrate using a deposition mask;
immersing the deposition mask into a cleaning solution;
removing the deposition mask from the cleaning solution and eliminating residual cleaning solution from the deposition mask; and
repeating forming the patterned light emitting layer using the cleaned deposition mask,
wherein the deposition mask includes:
a frame in which an opening through which a deposition material passes is defined; and
a mask sheet arranged on the frame, including a plurality of pattern regions overlapping the opening in a direction through which the deposition material passes are formed,
wherein the frame includes a groove extending in a first direction, a first channel extending in a second direction intersecting the first direction and communicating with the groove, and a second channel extending in a third direction intersecting the first and second directions and communicating with the first channel,
wherein the groove and the second channel communicate with each other through the first channel, and
wherein eliminating the residual cleaning solution from the deposition mask includes injecting fluid into the second channel.

15. The method according to claim 14, wherein the fluid sequentially flows through the second channel, the first channel, and the groove to dry the deposition mask.

16. The method according to claim 14, wherein the frame includes:
a pair of long side rods having a first length; and
a pair of short side rods having a second length shorter than the first length,
,
wherein the groove, the first channel, and the second channel are formed in the pair of long side rods,
wherein the deposition mask further includes a third channel extending in the first direction in at least one of the pair of short side rods and in communication with the second channel, and
wherein eliminating the residual cleaning solution from the deposition mask further includes injecting fluid into the third channel.

17. The method according to claim 16, wherein the second channel includes:
a (2_1)-th channel formed in any one of the pair of long side rods; and
a (2_2)-th channel formed in another one of the pair of long side rods,
wherein the (2_1)-th channel and the (2_2)-th channel communicate with each other through the third channel, and
wherein the fluid injected into the third channel flows into the (2_1)-th channel and the (2_2)-th channel.

18. The method according to claim 16, wherein the fluid sequentially flows through the third channel, the second channel, the first channel, and the groove to dry the deposition mask.

19. The method according to claim 14, wherein one side of the mask sheet and an opposite side of the mask opposite to the one side in the third direction overlap the frame in the second direction,
wherein the frame further includes a sub-groove extending in the third direction,
wherein the deposition mask further includes:
a sub-first channel communicating with the sub-groove and extending in the second direction; and
a third channel communicating with the sub-first channel and extending in the first direction,
wherein the sub-groove and the third channel communicate with each other through the sub-first channel,
wherein the second channel and the third channel are in communication with each other, and
wherein the fluid sequentially flows in the second channel, the third channel, the sub-first channel, and the sub-groove to dry the deposition mask.
